(19) United States
(12) Patent Application Publication
(10) Pub. No.: US 2025/0361423 A1
(43) Pub. Date: Nov. 27, 2025

(54) METHOD OF MANUFACTURING DISPLAY DEVICE, DISPLAY DEVICE MANUFACTURED BY METHOD OF MANUFACTURING DISPLAY DEVICE, AND ELECTRONIC DEVICE COMPRISING DISPLAY DEVICE

(71) Applicant: Samsung Display Co., LTD., Yongin-si (KR)

(72) Inventors: Jeong Weon SEO, Yongin-si (KR); Tae Woo PARK, Yongin-si (KR); Gwang Taek LEE, Yongin-si (KR)

(21) Appl. No.: 19/070,822

(22) Filed: Mar. 5, 2025

(30) Foreign Application Priority Data
May 27, 2024 (KR) 10-2024-0068514

(51) Int. Cl. C09J 5/00; H10K 59/12; H10K 59/80

(52) U.S. Cl. CPC C09J 5/00; H10K 59/1201; H10K 59/873

(57) ABSTRACT

A method of manufacturing a display device, a display device manufactured by the method, and an electronic device including the display device are provided. The method includes: providing a display panel; and providing a resin layer on the display panel. The providing of the resin layer includes: disposing a base resin layer on the display panel; changing a pose of the display panel and the base resin layer; precuring a portion of the base resin layer; changing a pose of the display panel and the base resin layer having the precured portion; and providing an entirely cured resin layer by entirely curing the base resin layer.

### CROSS-REFERENCE TO RELATED APPLICATION

The present application claims priority to and the benefit of Korean Patent Application No. 10-2024-0068514, filed on May 27, 2024, in the Korean Intellectual Property Office, the entire disclosure of which is incorporated herein by reference.

### BACKGROUND

### 1. Field

One or more embodiments of the present disclosure relate to a method of manufacturing a display device, a display device manufactured by the method, and an electronic device including the display device.

### 2. Description of the Related Art

Recently, the importance of information display devices has increased, leading to a dramatic expansion in their application fields. To facilitate the usage of a display device, it is often required to have (possess) one or more suitable or desired characteristics, including mechanical characteristics, heat dissipation capabilities, and/or the like. To this end, the display device may incorporate (include) one or more suitable functional layers to implement such characteristics and/or capabilities.

For instance, the display device may include a structure including a resin (e.g., composed of resin). Consequently, continuous research and development efforts have been directed towards manufacturing methods that effectively apply resin to form such structures (composed of resins).

### SUMMARY

One or more aspects of embodiments of the present disclosure are directed toward a method of manufacturing a display device, a display device manufactured by the method, and an electronic device including the display device, in which a resin layer may be formed to have a relatively or substantially flat outer surface.

One or more aspects of embodiments of the present disclosure are directed towards a method of manufacturing a display device, a display device manufactured by the method, and an electronic device including the display device, in which the method (manufacturing processes) may be simplified and streamlined.

One or more aspects of embodiments of the present disclosure are directed towards a method of manufacturing a display device, a display device manufactured by the method, and an electronic device including the display device, in which a risk that a resin layer will have a bump shape may be reduced. In other words, the method of manufacturing of the present disclosure substantially improves the evenness of a resin layer included in the display device.

Additional aspects will be set forth in part in the description which follows and, in part, will be apparent from the description, or may be learned by practice of the presented embodiments.

In accordance with one or more embodiments of the present disclosure, there is provided a method of manufacturing a display device, the method including: providing a display panel; and providing a resin layer on the display panel, wherein the providing of the resin layer includes: disposing a base resin layer on the display panel; changing a pose of the display panel and the base resin layer; precuring a portion of the base resin layer; changing a pose of the display panel and the base resin layer having the precured portion; and providing an entirely (fully) cured resin layer by entirely curing the base resin layer.

In one or more embodiments, in the disposing of the base resin layer, the base resin layer may have bump portions protruding from edge portions thereof.

In one or more embodiments, in the changing of the pose of the display panel and the base resin layer, a plane on which the display panel is arranged may have (from) an angle which is not normal (e.g., perpendicular) to a gravity direction. In other words, the plane on which the display panel is arranged may have (form) an angle with respect to a gravity direction but may not be normal (e.g., perpendicular) to the gravity direction.

In one or more embodiments, in the changing of the pose of the display panel and the base resin layer, a thickness direction of the display panel and a gravity direction may not be parallel to each other.

In one or more embodiments, in the changing of the pose of the display panel and the base resin layer, a thickness direction of the display panel and a gravity direction may have (form) an angle of about 30 degrees to about 90 degrees.

In one or more embodiments, the changing of the pose of the display panel and the base resin layer may include moving at least a portion of the base resin layer along a gravity direction.

In one or more embodiments, the changing of the pose of the display panel and the base resin layer may include accelerating movement of the base resin layer.

In one or more embodiments, the accelerating (of movement of the base resin layer) may include at least one of an operation of vibrating the base resin layer, an operation of applying vapor to the base resin layer, or an operation of applying thermal energy to the base resin layer.

In one or more embodiments, the base resin layer may include a first area and a second area. In the precuring, the first area may be positioned upwardly of (e.g., above) the second area with respect to a gravity direction. A thickness of the base resin layer in the second area may be thicker than a thickness of the base resin layer in the first area.

In one or more embodiments, the precuring may include precuring a portion of the base resin layer in the first area without applying a precuring process on another portion of the base resin layer in the second area.

In one or more embodiments, in the precuring, a portion of the base resin layer, to which a precuring process is not applied, may be moved in a direction toward the second area from the first area. For example, a portion of the base resin layer that is not precured may move in a direction toward the second area from the first area.

In one or more embodiments, in the changing of the pose of the display panel and the base resin layer having the precured portion, the first area may be positioned downwardly of (e.g., below) the second area with respect to a gravity direction.

In one or more embodiments, in the changing of the pose of the display panel and the base resin layer having the precured portion, the base resin layer in the second area may have a non-cured state, and be moved in a direction toward the first area from the second area by gravity.

In one or more embodiments, in the changing of the pose of the display panel and the base resin layer having the precured portion, the thickness of the base resin layer in the second area may be decreased, and the thickness of the base resin layer in the first area may be increased.

In one or more embodiments, in the changing of the pose of the display panel and the base resin layer having the precured portion, a portion of the base resin layer in the first area, which has a precured surface, may be covered by another portion of the base resin layer, which is not cured.

In one or more embodiments, the changing of the pose of the display panel and the base resin layer having the precured portion may include rotating the display panel and the base resin layer having the precured portion by about 180 degrees after the precuring.

In one or more embodiments, in the providing of the entirely cured resin layer (e.g., in the entirely curing of the resin layer), a thickness direction of the display panel may have (form) an angle with a gravity direction (e.g., the thickness direction of the display panel may form an angle with the direction of gravity).

In one or more embodiments, each of the precuring and the entirely curing may be a process using a curing method based on ultraviolet (UV) light. The disposing of the base resin layer may include forming the base resin layer, based on one selected from among an inkjet process, a slit coating process, and a jetting process.

In one or more embodiments, the method may further include forming an additional resin layer under the display panel. The forming of the additional resin layer may include: forming a base lower resin layer under the display panel; rotating the base lower resin layer and the display panel and then performing a precuring process on a portion of the base lower resin layer; additionally rotating the partially precured base lower resin layer and the display panel; and performing an entirely curing process on the base lower resin layer.

In accordance with one or more embodiments of the present disclosure, there is provided a display device manufactured according to the method.

In accordance with one or more embodiments of the present disclosure, there is provided an electronic device. The electronic device may include: a processor configured to provide input image data; the display device being configured to display an image based on the input image data and including sub-pixel areas; and a power supply configured to supply power to the display device.

### BRIEF DESCRIPTION OF THE DRAWINGS

Example embodiments will now be described more fully hereinafter with reference to the accompanying drawings; however, they may be embodied in different forms and should not be construed as limited to example embodiments set forth herein. Rather, these embodiments are provided so that this disclosure will be thorough and complete, and will fully convey the scope of the example embodiments to those skilled in the art.

In the drawings, dimensions may be exaggerated for clarity of illustration. It will be understood that if (e.g., when) an element is referred to as being “between” two elements, it may be the only element between the two elements, or one or more intervening elements may also be present therebetween. In addition, like reference numerals may refer to like elements throughout the present disclosure, and duplicative descriptions thereof may not be provided.

FIG. 1 is a schematic plan view illustrating a display device in accordance with one or more embodiments of the present disclosure.

FIG. 2 is a schematic sectional view illustrating a display device in accordance with one or more embodiments of the present disclosure.

FIG. 3 is a flowchart illustrating a method of manufacturing a display device in accordance with one or more embodiments of the present disclosure.

FIG. 4 is a flowchart illustrating process steps (e.g., acts or tasks) included in a step (e.g., an act or a task) of providing a resin layer on a display panel in accordance with one or more embodiments of the present disclosure.

FIGS. 5-9 are schematic sectional views illustrating process steps (e.g., acts or tasks) of the method of manufacturing the display device in accordance with one or more embodiments of the present disclosure.

FIG. 10 is a schematic block diagram illustrating an electronic device including a display device in accordance with one or more embodiments of the present disclosure.

FIG. 11 is a schematic diagram illustrating an example where the electronic device of FIG. 10 is implemented as a smartphone.

FIG. 12 is a schematic diagram illustrating an example where the electronic device of FIG. 10 is implemented as a tablet computer.

### DETAILED DESCRIPTION

The present disclosure may be practiced in many manners with one or more suitable changes and different forms, therefore here only illustrates in more details with certain examples. However, these examples do not limit to certain shapes or manners but apply to all the changes and equivalent materials and replacements. The drawings included are illustrated a fashion where the drawings may be expanded for the better understanding.

It will be understood that, although the terms “first”, “second”, and/or the like. may be used herein to describe one or more suitable elements, these elements should not be limited by these terms. These terms are only used to distinguish one element from another element. Thus, a “first” element discussed could also be termed a “second” element without departing from the teachings of the present disclosure. As utilized herein, the singular forms “a,” “an,” “one,” and “the” are intended to include the plural forms as well, unless the context clearly indicates otherwise. Further, the use of “may” when describing embodiments of the present disclosure refers to “one or more embodiments of the present disclosure.

It will be further understood that the terms “comprise(s)/comprising,” “include(s)/including,” “have (has)/having”, and/or the like, if (e.g., when) used in this disclosure, specify the presence of stated features, integers, steps, operations, elements, and/or components, but do not preclude the presence and/or addition of one or more other features, integers, steps, operations, elements, components, and/or groups thereof. Further, an expression that an element such as a layer, a region, a substrate, or a plate is placed “on” or “above” another element indicates not only embodiments in which the element is placed “directly on” or “just above” the other element but also embodiments in which a further element may be interposed between the element and the other element. In addition, an expression that an element such as a layer, a region, a substrate, or a plate is placed “beneath” or “below” another element indicates not only embodiments in which the element is placed “directly beneath” or “just below” the other element but also embodiments in which a further element may be interposed between the element and the other element. In contrast, when an element is referred to as being “directly on,” “just above,” “directly beneath”, or “just below” another element, there are no intervening elements present therebetween.

One or more embodiments of the present disclosure relate to a method of manufacturing a display device, a display device manufactured by the method, and an electronic device including the display device. Hereinafter, a method of manufacturing a display device, a display device manufactured by the method, and an electronic device including the display device in accordance with one or more embodiments of the present disclosure will be described in more detail with reference to the accompanying drawings.

First, a display device DD manufacturing according to a method of manufacturing the display device DD in accordance with one or more embodiments of the present disclosure will be described.

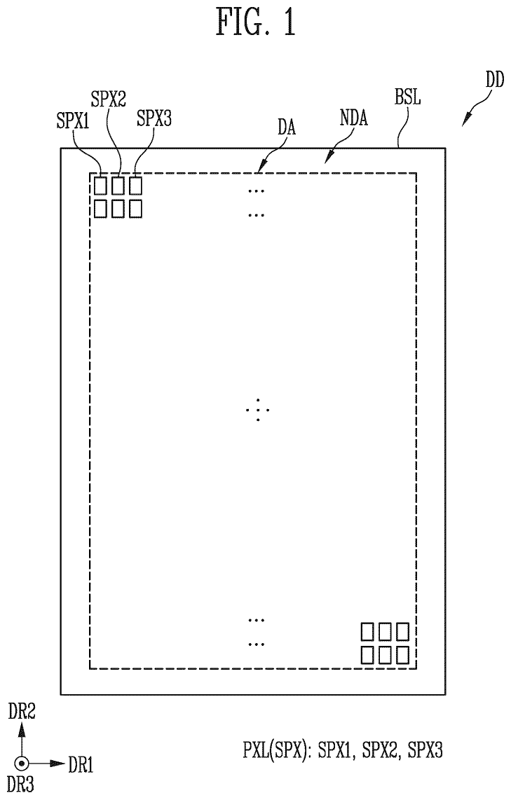

FIG. 1 is a schematic plan view illustrating a display device in accordance with one or more embodiments of the present disclosure.

A plane defined in this disclosure is a plane extending in a first direction DR1 and a second direction DR2, as shown in FIG. 1, and may be defined with respect to a plane on which a base layer BSL is arranged. In one or more embodiments, a third direction DR3 may be a thickness direction of the base layer BSL. The third direction DR3 may be a light output direction of the display device DD. A plan view, in this context, refers to a view of the plane extending in the first direction DR1 and the second direction DR2, as seen from above, in the third direction DR3.

Referring to FIG. 1, the display device DD may include a base layer BSL and pixels PXL on the base layer BSL. In one or more embodiments, the display device DD may further include a driving circuit (e.g., a scan driver and a data driver) for driving the pixels PXL, lines, and pads.

The display device DD (or the base layer BSL) may include a display area DA and a non-display area NDA. The non-display area NDA may refer to an area except the display area DA. The non-display area NDA may be around (e.g., surround) at least a portion of the display area DA.

The base layer BSL may form a base surface of the display device DD. The base layer BSL may be a rigid or flexible substrate or a rigid or flexible film. For example, in one or more embodiments, the base layer BSL may include a glass material. In one or more embodiments, the base layer BSL may include a silicon material. In one or more embodiments, the base layer BSL may include a polyimide. However, embodiments of the present disclosure are not limited thereto.

The display area DA may refer to an area in which the pixels PXL are arranged. The non-display area NDA may refer to an area in which the pixels PXL are not arranged. The driving circuit, the lines, and the pads, which are connected to the pixels PXL of the display area DA, may be arranged in the non-display area NDA.

In accordance with one or more embodiments, the pixels PXL (or sub-pixels SPX) may be arranged according to a stripe arrangement structure, a PENTILE® arrangement structure (for example, an RGBG matrix, an RGBG structure, or an RGBG matrix structure), and/or the like. However, embodiments of the present disclosure are not limited thereto, and one or more suitable pixel arrangements may be applied in the present disclosure. PENTILE® is a duly registered trademark of Samsung Display Co., Ltd.

In accordance with one or more embodiments, a pixel PXL (or sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be a sub-pixel. At least one first sub-pixel SPX1, at least one second sub-pixel SPX2, and at least one third sub-pixel SPX3 may form a pixel unit capable of emitting light of one or more suitable colors.

In one or more embodiments, each of the first sub-pixel SPX1, the second sub-pixel SPX2, and the third sub-pixel SPX3 may be to emit light of a color.

For example, in one or more embodiments, the first sub-pixel SPX1 may be a red pixel emitting light of red (e.g., a first color), the second sub-pixel SPX2 may be a green pixel emitting light of green (e.g., a second color), and the third sub-pixel SPX3 may be a blue pixel emitting light of blue (e.g., a third color). The red pixel may provide light in a wavelength band of 600 nm to 750 nm. The green pixel may provide light in a wavelength band of 480 nm to 560 nm. The blue pixel may provide light in a wavelength band of 370 nm to 460 nm.

In accordance with one or more embodiments, the number of second sub-pixels SPX2 may be greater than the number of first sub-pixels SPXL1 and the number of third sub-pixels SPXL3. However, the color, kind, and/or number of first, second, and third sub-pixels SPX1, SPX2, and SPX3 constituting each pixel unit are not limited to any specific example.

In one or more embodiments, the display device DD may be a flexible display device. For example, the display device DD may be one selected from among a bendable display device, a foldable display device, and a rollable display device.

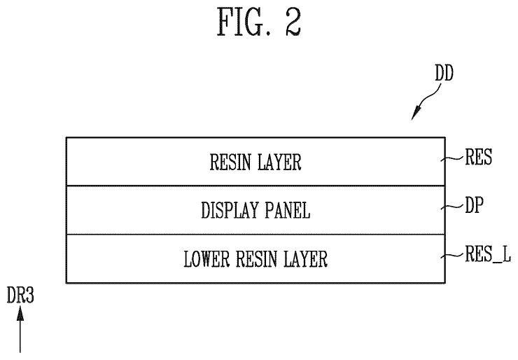

FIG. 2 is a schematic sectional view illustrating a display device in accordance with one or more embodiments of the present disclosure.

Referring to FIG. 2, the display device DD in accordance with one or more embodiments of the present disclosure may include a structure including a resin.

The display device may include a display panel DP and a resin layer RES on the display panel DP. In one or more embodiments, the display device DD may further include a lower resin layer RES_L arranged under the display panel DP.

The display panel DP may be configured to emit light. For example, the display panel DP may include a light source. For example, in one or more embodiments, the display panel DP may include an Organic Light Emitting Diode (OLED) including an organic material. In one or more embodiments, the display panel DP may include an inorganic light emitting diode including an inorganic material. However, embodiments of the present disclosure are not limited thereto. In one or more embodiments, the display panel DP may further include a circuit element for driving a light emitting diode. The circuit element may include one or more transistors and one or more capacitors, and the structure of the circuit element is not particularly limited.

The resin layer RES may be arranged on the display panel DP (e.g., on a first surface of the display panel DP) with respect to a display direction of the display device DD (e.g., the third direction DR3). The resin layer RES may have an end portion overlapping with the display panel DP.

The resin layer RES may include one or more suitable resin materials. For example, in one or more embodiments, the resin layer RES may include at least one selected from the group consisting of urethane resins, acrylic resins, epoxy resins, phenolic resins, polyamide resins, polyimide resins, polyester resins, polyphenylenesulfide resins, and benzocyclobutene (BCB)-based polymers. However, embodiments of the present disclosure is not necessarily limited to the above-described examples.

The resin layer RES may be arranged on the display panel DP, to allow light to be transmitted therethrough, like a cover glass. The resin layer RES may allow optical information to be appropriately or suitably transmitted therethrough, and excellent or suitable display quality may be provided when the display device DD provides optical information.

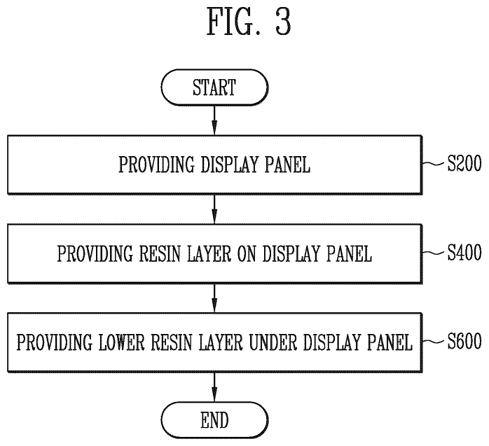

The resin layer RES may be manufactured according to a method of manufacturing the display device DD of the present disclosure, which will be described after FIG. 3. A top surface of the resin layer RES may have a relatively flat outer surface, and may have an excellent or suitable flatness characteristic. For example, the resin layer RES may not have a shape unintendedly extending or having an excessively (or substantially) protruding portion, such as a bump structure. The display quality of the display device DD may thus be more excellently provided. This will be described in more detail later with reference to FIG. 3.

The lower resin layer RES_L may be arranged at a lower portion of the display device DD (e.g., on a second surface of the display panel DP opposite to the first surface of the display panel DP). The lower resin layer RES_L may have an end portion overlapping with the display panel DP.

The lower resin layer RES_L may include one or more suitable resin materials. For example, in one or more embodiments, the lower resin layer RES_L may include at least one selected from the group consisting of urethane resins, acrylic resins, epoxy resins, phenolic resins, polyamide resins, polyimide resins, polyester resins, polyphenylenesulfide resins, and benzocyclobutene (BCB)-based polymers. However, the embodiments of present disclosure are not necessarily limited to the above-described example.

The lower resin layer RES_L may be arranged under the display panel DP, to improve a heat dissipation characteristic, and improve impact resistance of the display device DD.

Similarly to the resin layer RES, the lower resin layer RES_L may also be manufactured according to the method of manufacturing the display device DD of the present disclosure, which will be described after FIG. 3. The lower resin layer RES_L may have a relatively flat outer surface.

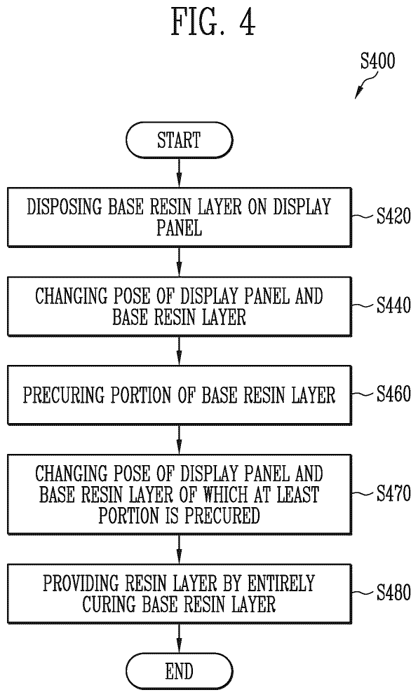

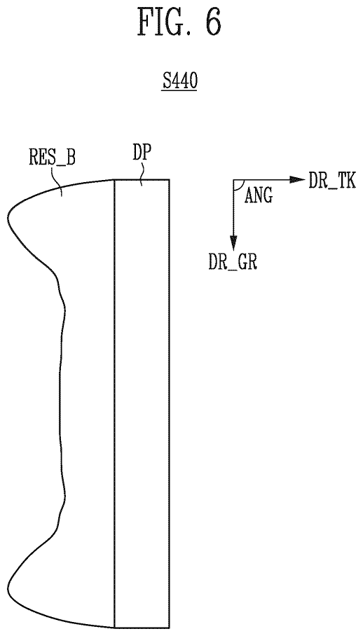

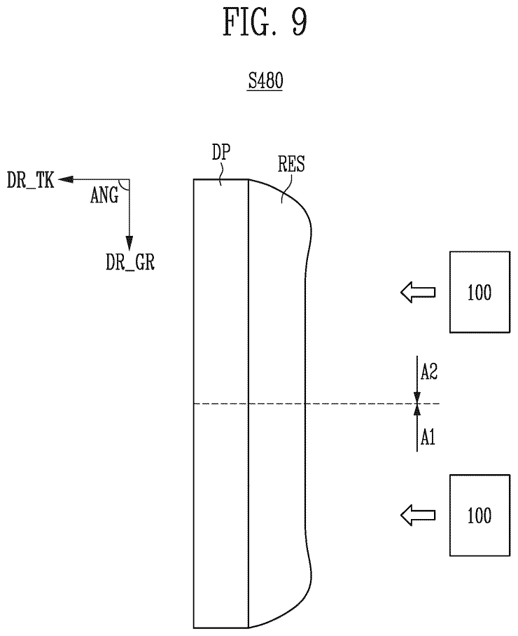

In one or more embodiments, beside the display device DD, the display panel DP itself may also include a layer including a resin (e.g., also include a layer composed of resin). The layer including the resin, which is included in the display panel DP, may also be manufactured based on a method of providing the resin layer RES, which will be described with reference to FIGS. 4 to 9. That is, this resin layer within the display panel DP may also be manufactured using the method for providing the resin layer RES, as described with reference to FIGS. 4 to 9. Consequently, the layer including the resin, which is included in the display panel DP, may also achieve excellent or suitable flatness characteristic.

Next, a method of manufacturing a display device DD in accordance with one or more embodiments of the present disclosure will be described with reference to FIGS. 3 to 9. In FIGS. 3 to 9, descriptions of portion that overlaps with the portions described above will be simplified or will not be repeated for conciseness.

FIG. 3 is a flowchart illustrating a method of manufacturing a display device in accordance with one or more embodiments of the present disclosure.

FIG. 4 is a flowchart illustrating process steps (e.g., acts or tasks) included in a step (e.g., an act or a task) of providing a resin layer on a display panel in accordance with one or more embodiments of the present disclosure.

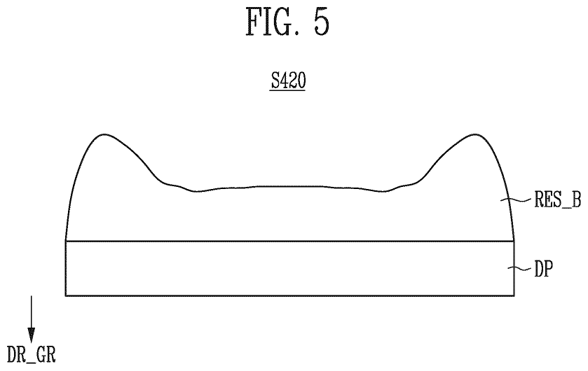

FIGS. 5 to 9 are schematic sectional view illustrating process steps (e.g., acts or tasks) of the method of manufacturing the display device in accordance with one or more embodiments of the present disclosure.

Referring to FIG. 3, the method of manufacturing the display device DD may include step (e.g., act or task) S200 of providing a display panel, step (e.g., act or task) S400 of providing a resin layer on the display panel, and step (e.g., act or task) S600 of providing a lower resin layer under the display panel.

Referring to FIG. 4, the step (e.g., act or task) S400 of providing the resin layer on the display panel may include step (e.g., act or task) S420 of disposing a base resin layer on the display panel, step (e.g., act or task) S440 of changing a pose of the display panel and the base resin layer, step (e.g., act or task) S460 of precuring a portion of the base resin layer, step (e.g., act or task) S470 of changing a pose of the display panel and the base resin layer of which at least a portion is precured, and step (e.g., act or task) S480 of providing the resin layer by entirely curing the base resin layer.

Referring to FIG. 3, in the step (e.g., act or task) S200 of providing the display panel, a display panel DP including a light source such as a light emitting element may be manufactured. For example, in this step (e.g., act or task), circuit elements may be patterned on a substrate, based on a process of art for forming a backplane structure, and a light emitting element electrically connected to a circuit element may be provided. The light emitting element may be provided based on one or more suitable process methods according to a kind thereof. For example, if (e.g., when) the light emitting element is an organic light emitting element, the light emitting element may be provided based on a deposition process and/or the like. However, embodiments of the present disclosure are not limited thereto.

Referring to FIGS. 3 to 5, in the step (e.g., act or task) S400 of providing the resin layer on the display panel, the step (e.g., act or task) S420 of disposing the base resin layer on the display panel may be performed.

In the step (e.g., act or task) S420, a base resin layer RES_B for forming a resin layer RES may be disposed on the display panel DP. In one or more embodiments, the base resin layer RES_B may be applied based on one or more suitable methods. For example, in one or more embodiments, the base resin layer RES_B may be formed based on one selected from among an inkjet process, a slit coating process, and a jetting process. However, embodiments of the present disclosure are not limited to any specific example.

In the step (e.g., act or task) S420, the base resin layer RES_B disposed on the display panel DP may have a relatively non-uniform profile. For example, the base resin layer RES_B may have bump portions protruding from edge portions thereof.

Referring to FIGS. 3, 4, and 6, in the step (e.g., act or task) S400 of providing the resin layer on the display panel, the step (e.g., act or task) S440 of changing the pose of the display panel and the base resin layer may be performed.

In the step (e.g., act or task) S440, the display panel DP and the base resin layer RES_B may be rotated together, and the pose of the display panel DP and the base resin layer RES_B may be changed.

In the step (e.g., act or task) S440, in one or more embodiments, a plane on which the display panel DP is arranged may be roughly parallel to a gravity direction DR_GR. In one or more embodiments, the plane on which the display panel DP is arranged may have (form) an angle which is not normal (e.g., perpendicular) to the gravity direction DR_GR. In other words, the plane on which the display panel DP is arranged may have (form) an angle with respect to the gravity direction DR_GR but may not be normal (e.g., perpendicular) to the gravity direction DR_GR.

In other words, referring to FIGS. 3, 4, and 6, during the step S400 of providing the resin layer on the display panel, the step S440 involves changing the pose of the display panel and the base resin layer by rotating them together. In this step, the plane on which the display panel is arranged may be roughly or substantially parallel to the gravity direction DR_GR or at an angle that is not perpendicular or normal to the gravity direction.

Also, in the step (e.g., act or task) S440, a thickness direction DR_TK of the display panel DP and the gravity direction DR_GR may not be parallel to each other. In one or more embodiments, the thickness direction DR_TK of the display panel DP may correspond to a direction in which the display panel DP and the base resin layer RES_B are adjacent to each other. For example, the thickness direction DR_TK of the display panel DP and the gravity direction DR_GR may have (form) an angle ANG. In one or more embodiments, the angle ANG may be 90 degrees. In one or more embodiments, the angle ANG may be less than 90 degrees. In one or more embodiments, the angle ANG may be 30 degrees to 90 degrees.

In the step (e.g., act or task) S440, as the base resin layer RES_B is rotated, at least a portion of the base resin layer RES_B may be moved in the gravity direction DR_GR. For example, because the base resin layer RES_B may include a non-cured resin material, the base resin layer RES_B may have liquidity. Accordingly, at least a portion of the base resin layer RES_B may be applied with an external force opposite to (e.g., facing) an opposite end portion of an end portion of the display panel DP.

In the step (e.g., act or task) S440, in one or more embodiments, in order to accelerate movement of the base resin layer RES_B, an additional movement acceleration operation may be applied to the base resin layer RES_B. For example, in one or more embodiments, in the step (e.g., act or task) S440, the base resin layer RES_B and the display panel DP may be vibrated, and thus the liquidity of the base resin layer RES_B may be increased. In one or more embodiments, in the step (e.g., act or task) S440, an additional external force (e.g., vapor, gas, and/or the like) may be applied to the base resin layer RES_B and the display panel DP, and thus the liquidity of the base resin layer RES_B may be increased. In one or more embodiments, in the step (e.g., act or task) S440, thermal energy may be applied to the base resin layer RES_B and the display panel DP, and thus the liquidity of the base resin layer RES_B may be increased. In one or more embodiments, in order to accelerate the movement of the base resin layer RES_B, at least one of an operation of vibrating the base resin layer RES_B, an operation of applying vapor to the base resin layer RES_B, or an operation of applying thermal energy to the base resin layer RES_B may be performed.

Referring to FIGS. 3, 4, and 7, in the step (e.g., act or task) S400 of providing the resin layer on the display panel, the step (e.g., act or task) S460 of precuring the portion of the resin layer may be performed.

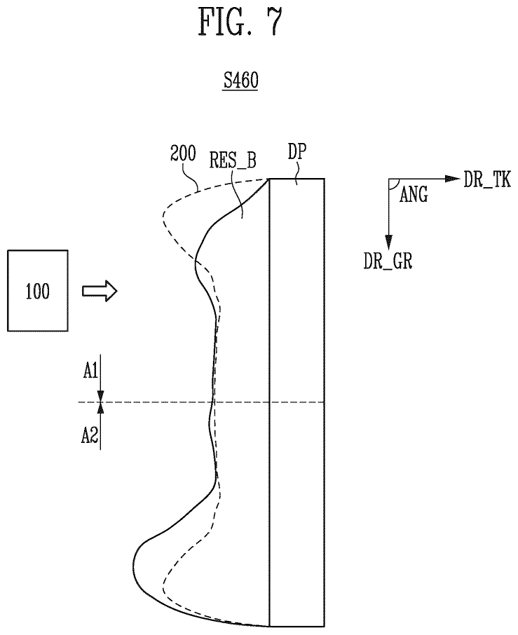

As described above, as the display panel DP and the base resin layer RES_B are rotated, at least a portion of the base resin layer RES_B may be moved along the gravity direction DR_GR, for example by gravity. For convenience of description, a position of the base resin layer RES_B of a state 200 before the base resin layer RES_B is moved by gravity is indicated by a dotted line in FIG. 7. Accordingly, a thickness of the base resin layer RES_B in a second area A2 defined at a lower portion with respect to the gravity direction DR_GR may be greater than a thickness of the base resin layer RES_B in a first area A1 defined at an upper portion with respect to the gravity direction DR_GR. For example, a maximum thickness of the base resin layer RES_B in the first area A1 may be smaller than a maximum thickness of the base resin layer RES_B in the second area A2.

In the step (e.g., act or task) S460, a precuring process on a portion of the base resin layer RES_B may be performed. For example, the base resin layer RES_B may include the first area A1 and the second area A2. In the step (e.g., act or task) S460, a portion of the base resin layer RES_B in the first area A1 may be precured by a resin curing apparatus 100. In the step (e.g., act or task) S460, another portion of the base resin layer RES_B in the second area A2 may not be cured by the resin curing apparatus 100.

In one or more embodiments, in the step (e.g., act or task) S460, the first area A1 may be formed and positioned upwardly of the second area A2 with respect to the gravity direction DR_GR. For example, in one or more embodiments, a relatively upper portion of the base resin layer RES_B may be precured in the step (e.g., act or task) S460.

In this disclosure, the term “precuring” may refer to a curing (e.g., an intermediate curing, a middle curing) step (e.g., act or task) performed before a final curing process. For example, it may be understood that at least a portion of the base resin layer RES_B is cured in the precuring process.

The resin curing apparatus 100 may cure the base resin layer RES_B, based on one or more suitable methods. For example, in one or more embodiments, the resin curing apparatus 100 may be an ultraviolet (UV) application apparatus capable of curing resin, using UV. However, embodiments of the present disclosure are not necessarily limited thereto.

In one or more embodiments, a portion of the base resin layer RES_B (e.g., the first area A1) may be precured, while another portion of the base resin layer RES_B (e.g., the second area A2) remains uncured. Therefore, the base resin layer RES_B may have liquidity. For example, in the step (e.g., act or task) S460, at least a portion of the base resin layer RES_B may be moved at the same time when the precuring process on a portion of the base resin layer RES_B is performed.

Referring to FIGS. 3, 4, and 8, in the step (e.g., act or task) S400 of providing the resin layer on the display panel, the step (e.g., act or task) S470 of changing the pose of the display panel and the base resin layer of which the at least a portion is precured may be performed.

In the step (e.g., act or task) S470, the display panel DP and the base resin layer RES_B of which at least a portion is precured may be rotated together. The pose of the display panel DP and the base resin layer RES_B may be changed. For example, in one or more embodiments, the display panel DP and the base resin layer RES_B may be rotated by 180 degrees with respect to the above-described state of step (e.g., act or task) S440.

In the step (e.g., act or task) S470, a portion of the base resin layer RES_B having a precured surface HS may be a lower portion with respect to the gravity direction DR_GR, and another portion of the base resin layer RES_B having a non-cured surface NHS may be an upper portion with respect to the gravity direction DR_GR. For example, the display panel DP and the base resin layer RES_B may be rotated such that the first area A1 is arranged and positioned downwardly of the second area A2 with respect to the gravity direction DR_GR.

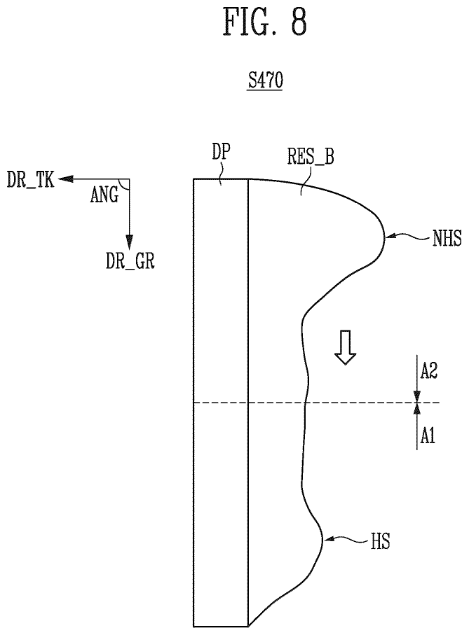

In the step (e.g., act or task) S470, because at least a portion of the base resin layer RES_B is not cured, the base resin layer RES_B may have liquidity. For example, the non-cured portion of the base resin layer RES_B in the second area A2 may be moved in a direction toward the first area A1 from the second area A2 by the gravity, as shown by an arrow in FIG. 8.

In the step (e.g., act or task) S470, the thickness of the base resin layer RES_B in the second area A2 may be decreased, and the thickness of the base resin layer RES_B in the first area A1 may be increased.

In the step (e.g., act or task) S470, in the first area A1, at least a portion of the non-cured base resin layer RES_B may cover the precured surface HS. For example, because a portion of the non-cured base resin layer RES_B moved on the precured surface HS in the first area A1 may be provided, an interface may be observed at at least a portion inside the resin layer RES provided by performing subsequent processes.

Referring to FIGS. 3, 4, and 9, in the step (e.g., act or task) S400 of providing the resin layer on the display panel, the step (e.g., act or task) S480 of providing the resin layer by entirely curing the base resin layer may be performed.

In the step (e.g., act or task) S480, a curing process on the entire base resin layer RES_B including the first area A1 and the second area A2 may be performed by the resin curing apparatus 100. The base resin layer RES_B may be entirely cured, and the entirely cured resin layer RES may be provided. In one or more embodiments, an entirely curing process may be performed in a state in which the thickness direction DR_TK and the gravity direction DR_GR still form an angle therebetween (e.g., the thickness direction DR_TK and the gravity direction DR_GR are not parallel to each other). Accordingly, the curing process and a process of moving the base resin layer RES_B which is not still cured may be partially concurrently (e.g., simultaneously) performed, and process steps may be relatively simplified.

As described above, a portion of the base resin layer RES_B may be moved by the gravity such that the surface uniformity of the base resin layer RES_B is compensated and improved. For example, a step (e.g., act or task) of controlling the pose of the base resin layer RES_B such that portions of the base resin layer RES_B having a relatively thick thicknesses face (e.g., being positioned as) the upper portion with respect to the gravity direction DR_GR may be applied to process steps. Accordingly, the base resin layer RES_B may be provided to have a roughly uniform surface profile and have a relatively flat outer surface after the entirely curing process is performed, and the resin layer RES in which an undesired protruding shape, such as a bump shape, is minimized or reduced may be provided.

In accordance with one or more embodiments, process steps of manufacturing may be simplified. In a manufacturing process, when a resin structure including a resin is formed, a risk that the resin structure will have bump shapes roughly protruding from edge portions thereof due to liquidity of the resin structure may occur. The visibility and display quality of the display device DD may be damaged or impaired due to an application field of the resin structure, and a risk that it will be difficult for the resin structure to be suitably attached to the display panel DP may exist. Therefore, an additional process of cutting the edge portions of the resin structure may be desired or required. Here, in accordance with one or more embodiments of the present disclosure, the surface uniformity of the resin layer RES is improved and becomes excellent or suitable, and the above-described risk may be reduced. Therefore, any additional process may not be further required.

In other words, referring to FIGS. 3 to 5, during the step S400 of providing the resin layer on the display panel, step S420 involves disposing the base resin layer RES_B on the display panel (DP) using methods such as inkjet, slit coating, or jetting processes. Initially, the base resin layer may have a non-uniform profile with bumps at the edges. In step S440, the pose of the display panel and the base resin layer is changed by rotating them together, aligning the plane of the display panel roughly parallel to or at an angle with the gravity direction DR_GR. This rotation helps move the liquid base resin layer, potentially using additional forces like vibration, vapor, or thermal energy to enhance its liquidity. In step S460, a precuring process is performed on a portion of the base resin layer, resulting in suitable thicknesses in various areas due to gravity. The term “precuring” refers to an intermediate curing step before the final curing process, which can be done using methods like UV application. In step S470, the display panel and the partially precured base resin layer are rotated again, changing their pose so that the precured surface faces downward. This causes the uncured portion to move due to gravity, evening out the thickness. Finally, in step S480, the entire base resin layer is cured, resulting in a uniformly flat outer surface. This method improves the surface uniformity of the resin layer, reducing the need for additional processing steps and minimizing defects such as bumps.

Referring to FIG. 3, the step (e.g., act or task) S600 of providing the lower resin layer under the display panel may be further performed. In the step (e.g., act or task) S600 of providing the lower resin layer under the display panel, processes for forming a lower resin layer RES_L under the display panel DP may be sequentially applied.

In one or more embodiments, a process for forming the lower resin layer RES_L may be substantially identical to the process steps described above with reference to FIGS. 4 to 9. For example, a base lower resin for forming the lower resin layer RES_L may be formed under the display panel DP, a partially precuring process on the base lower resin layer may be performed after the base lower resin layer and the display panel DP are rotated, the partially precured base lower resin layer and the display panel DP may be then additionally rotated, and an entirely curing process on the base lower resin layer may be performed after another portion of the base lower resin layer, which is not cured, is moved, thereby providing the lower resin layer RES_L.

Accordingly, the display device DD including the resin layer RES may be provided. In one or more embodiments, the display device DD further including the lower resin layer RES_L may be provided.

Hereinafter, an electronic device 1000 including the display device DD in accordance with one or more embodiments will be described.

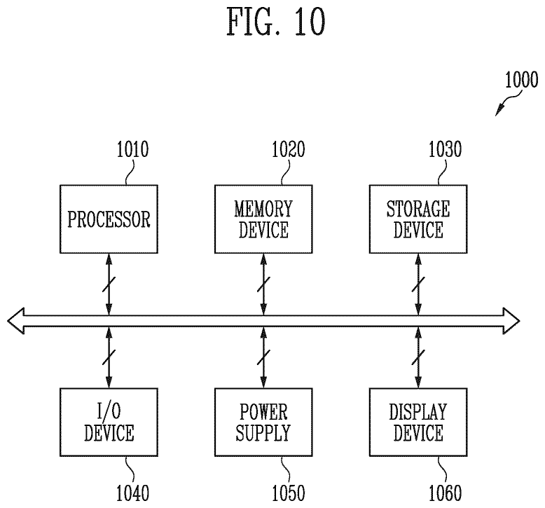

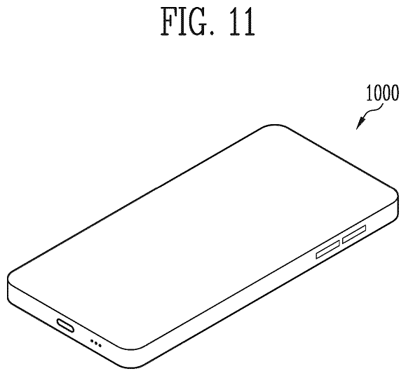

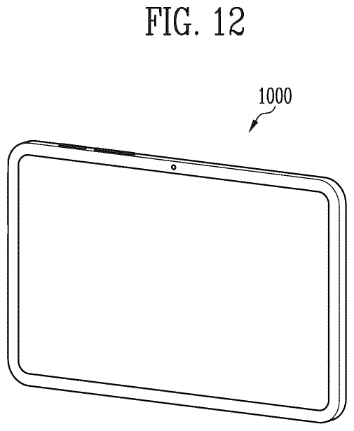

FIG. 10 is a schematic block diagram illustrating an electronic device 1000 including a display device in accordance with one or more embodiment of the present disclosure. FIG. 11 is a schematic diagram illustrating an example where the electronic device 1000 of FIG. 10 is implemented as a smartphone. FIG. 12 is a schematic diagram illustrating an example where the electronic device 1000 of FIG. 10 is implemented as a tablet computer.

Referring to FIGS. 10 to 12, the electronic device 1000 may include a processor 1010, a memory device 1020, a storage device 1030, an input/output (I/O) device 1040, a power supply 1050, and a display device 1060. The display device 1060 may be the display device DD of FIG. 1. The electronic device 1000 may further include various ports for communication with a video card, a sound card, a memory card, a USB device, and/or other systems. In one or more embodiments, as illustrated in FIG. 11, the electronic device 1000 may be a smartphone. In one or more embodiments, as illustrated in FIG. 12, the electronic device 1000 may be a tablet computer. However, the aforementioned examples are explanatory, and the electronic device 1000 is not necessarily limited to the aforementioned examples. For example, the electronic device 1000 may be a cellular phone, a video phone, a smart pad, a smartwatch, a navigation device for vehicles, a computer monitor, a laptop computer, a head-mounted display device, or the like.

The processor 1010 may perform specific calculations or tasks. In one or more embodiments, the processor 1010 may include at least one of a central processing unit, an application processor, a graphic processing unit, a communication processor, an image signal processor, a controller, or the like. The processor 1010 may be connected to other components through an address bus, a control bus, a data bus, and the like. In one or more embodiments, the processor 1010 may be connected to an expansion bus such as a peripheral component interconnect (PCI) bus. In one or more embodiments, the processor 1010 may provide input image data to the display device 1060. Hence, the display device 1060 may display an image based on the input image data provided from the processor 1010.

The memory device 1020 may store data needed to perform operations of the electronic device 1000. The memory device 1020 may function as a working memory and/or a buffer memory for the processor 1010. For example, the memory device 1020 may include one or more volatile memory devices such as a dynamic random access memory (DRAM) device, a static random access memory (SRAM) device, and/or a mobile DRAM device.

The storage device 1030 may store data in response to control signals or data from the processor 1010. The storage device 1030 may include one or more non-volatile storages to retain the data even when the electronic device 1000 is powered off. In some embodiments, the storage device 1030 may include a solid state drive (SSD), a hard disk drive (HDD), a CD-ROM, and/or the like.

The I/O device 1040 may include one or more input devices such as a keyboard, a keypad, a touchpad, a touch screen, and a mouse, and one or more output devices such as a speaker and a printer. In one or more embodiments, the display device 1060 may be integrated with the I/O device 1040.

The power supply 1050 may supply power needed to perform the operation of the electronic device 1000. For example, the power supply 1050 may include a power management integrated circuit (PMIC). In one or more embodiments, the power supply 1050 may supply power to the display device 1060.

The display device 1060 may display images in response to image data signals and/or control signals from the processor 1010. The display device 1060 may be connected to other components through the buses or other communication links.

In accordance with one or more embodiments of the present disclosure, there are provided a method of manufacturing a display device, a display device manufactured by the method, and an electronic device including the display device, in which a resin layer may be formed to have a relatively flat outer surface.

In accordance with one or more embodiments of the present disclosure, there are provided a method of manufacturing a display device, a display device manufactured by the method, and an electronic device including the display device, in which manufacturing processes may be simplified.

In accordance with one or more embodiments of the present disclosure, there are provided a method of manufacturing a display device, a display device manufactured by the method, and an electronic device including the display device, in which a risk that a resin layer will have a bump shape may be reduced.

In the present disclosure, expressions such as “at least one of,” “one of,” and “selected from,” when preceding a list of elements, modify the entire list of elements and do not modify the individual elements of the list. For example, “at least one of a, b, or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof. The “/” utilized herein may be interpreted as “and” or as “or” depending on the situation.

In the context of the present application and unless otherwise defined, the terms “use,” “using,” and “used” may be considered synonymous with the terms “utilize,” “utilizing,” and “utilized,” respectively.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, or 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this disclosure, including the claims, to expressly recite any sub-range subsumed within the ranges expressly recited herein.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

The display device-manufacturing apparatus, the display device, the electronic devices/apparatus, or any other relevant apparatuses/devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that one or more suitable changes in form and details may be made without departing from the spirit and scope of the present disclosure as set forth in the appended claims and equivalents thereof.

What is claimed is:

1. A method, comprising:
providing a display panel; and
providing a resin layer on the display panel,
wherein the providing of the resin layer comprises:
disposing a base resin layer on the display panel;
changing a pose of the display panel and the base resin layer;
precuring a portion of the base resin layer;
changing a pose of the display panel and the base resin layer with the precured portion; and
entirely curing the base resin layer to provide a fully cured resin layer.

2. The method of claim 1, wherein, in the disposing of the base resin layer, the base resin layer has bump portions protruding from edge portions of the base resin layer.

3. The method of claim 1, wherein, in the changing of the pose of the display panel and the base resin layer, a plane on which the display panel is arranged forms an angle with respect to a gravity direction and is not perpendicular to the gravity direction.

4. The method of claim 1, wherein, in the changing of the pose of the display panel and the base resin layer, a thickness direction of the display panel and a gravity direction are not parallel to each other.

5. The method of claim 1, wherein, in the changing of the pose of the display panel and the base resin layer, a thickness direction of the display panel and a gravity direction form an angle of about 30 degrees to about 90 degrees.

6. The method of claim 1, wherein the changing of the pose of the display panel and the base resin layer comprises moving at least a portion of the base resin layer along a gravity direction.

7. The method of claim 6, wherein the changing of the pose of the display panel and the base resin layer comprises accelerating movement of the base resin layer.

8. The method of claim 7, wherein the accelerating comprises at least one of an operation of vibrating the base resin layer, an operation of applying vapor to the base resin layer, or an operation of applying thermal energy to the base resin layer.

9. The method of claim 1, wherein the base resin layer comprises a first area and a second area,
wherein, in the precuring, the first area is positioned above the second area with respect to a gravity direction, and
wherein a thickness of the base resin layer in the second area is thicker than a thickness of the base resin layer in the first area.

10. The method of claim 9, wherein the precuring comprises precuring a portion of the base resin layer in the first area without precuring another portion of the base resin layer in the second area.

11. The method of claim 10, wherein, in the precuring, a portion of the base resin layer that is not precured moves in a direction toward the second area from the first area.

12. The method of claim 11, wherein, in the changing of the pose of the display panel and the base resin layer having the precured portion, the first area is positioned below the second area with respect to the gravity direction.

13. The method of claim 12, wherein, in the changing of the pose of the display panel and the base resin layer having the precured portion, the base resin layer in the second area remains in a non-cured state and moves in a direction toward the first area from the second area by gravity.

14. The method of claim 13, wherein, in the changing of the pose of the display panel and the base resin layer having the precured portion, the thickness of the base resin layer in the second area decreases, and the thickness of the base resin layer in the first area increases.

15. The method of claim 13, wherein, in the changing of the pose of the display panel and the base resin layer having the precured portion, a portion of the base resin layer in the first area, which has a precured surface, is covered by another portion of the base resin layer that is not cured.

16. The method of claim 1, wherein the changing of the pose of the display panel and the base resin layer having the precured portion comprises rotating the display panel and the base resin layer with the precured portion by about 180 degrees after the precuring.

17. The method of claim 1, wherein, in the entirely curing of the resin layer, a thickness direction of the display panel forms an angle with a gravity direction.

18. The method of claim 1, wherein each of the precuring and the entirely curing utilizes a curing method based on ultraviolet light, and
wherein the disposing of the base resin layer comprises forming the base resin layer utilizing one selected from among an inkjet process, a slit coating process, and a jetting process.

19. The method of claim 1, further comprising forming an additional resin layer under the display panel,
wherein the forming of the additional resin layer comprises:
forming a base lower resin layer under the display panel;
rotating the base lower resin layer and the display panel and then performing a precuring process on a portion of the base lower resin layer;
additionally rotating a partially precured base lower resin layer and the display panel; and
performing an entirely curing process on the base lower resin layer.

20. An electronic device, comprising:
a processor configured to provide input image data;
a display device manufactured according to the method of claim 1, the display device being configured to display an image based on the input image data and including sub-pixel areas; and
a power supply configured to supply power to the display device.
